(19) United States
(12) Patent Application Publication
(10) Pub. No.: US 2006/0244101 A1
(43) Pub. Date: Nov. 2, 2006

(54) SEMICONDUCTOR APPARATUS AND PHYSICAL QUANTITY SENSING APPARATUS

(75) Inventors: Katsuyuki Uematsu, Hata-machi (JP); Katsumichi Ueyanagi, Matsumoto (JP)

Correspondence Address: ROSSI, KIMMS & McDOWELL LLP., P.O. BOX 826, ASHBURN, VA, 20146-0826, US

(73) Assignee: FUJI ELECTRIC DEVICE TECHNOLOGY CO., LTD., Tokyo (JP)

(21) Appl. No.: 11/278,429

(22) Filed: Apr. 3, 2006

(30) Foreign Application Priority Data
Apr. 28, 2005 (JP) 2005-133557

(51) Int. Cl. H01L 29/00

(52) U.S. Cl. 257/533

(57) ABSTRACT

In a semiconductor device, in particular a physical quantity sensing apparatus, the length and the width of the wiring connecting a sensor internal circuit and an output or power supply pad are adjusted so that the total parasitic resistance components R1 parasitic on the wiring and the sum Rf of the resistance values of resistors in the filter circuit for countermeasuring against electromagnetic noises satisfy the relational expression R1/Rf×100<25. Also, the length and the width of the wiring between the output or power supply pad and the capacitor(s) and the length and the width of the wiring between the capacitor(s) and the grounding pad are adjusted so that the impedance Za caused by the parasitic resistance component Ra and the inductance component La of the wiring between the output or power supply pad and the capacitor(s), the impedance Zk caused by the parasitic resistance component Rk and the inductance component Lk of the wiring between the capacitor(s) and the grounding pad, and the impedance Zc caused by the capacitance component of the capacitor(s) always satisfy the relational expression Za+Zk<Zc in the frequency range of the electromagnetic noises to be cut. The semiconductor apparatus and the physical quantity sensing apparatus are provided with countermeasures against electromagnetic noises to meet the demand for automotive sensors.

### BACKGROUND

Recently, various kinds of sensors, such as a pressure sensor, an acceleration sensor and a flow rate sensor, have been used to monitor the various states of an automobile during the stoppage and the running thereof. Since these sensors are indispensable to conduct advanced system controls for improving the environment and the comfortableness, more sensors are being used. Recently, the electromagnetic waves caused from the outside of the automobiles and the electromagnetic noises caused inside the automobiles have been increasing. Therefore, it has been required to provide the sensors with excellent countermeasures against electromagnetic noises.

FIG. 9 is a perspective view showing the external appearance of a conventional pressure sensor used in the intake manifold of an automobile engine. FIG. 10 is a cross sectional view of the conventional pressure sensor shown in FIG. 9 along the extending direction of the power supply terminal thereof. Referring now to FIGS. 9 and 10, the pressure sensor 1 includes a pressure detecting element 4 including a glass pedestal 3 and a semiconductor sensor chip 2 bonded to glass pedestal 3 by electrostatic bonding. The pressure detecting element 4 is fixed to the window section of a resin package 5 with an adhesive. The semiconductor sensor chip 2 includes a power supply pad, a grounding pad, and an output pad, electrically connected respectively to a power supply terminal 6, a grounding terminal 7, and an output terminal 8, extending through the resin package 5, via aluminum (Al) or gold (Au) wires 9. The window section of the resin package 5 is filled with gel (not illustrated).

The electromagnetic noises that adversely affect the sensor as described above include noises from the power supply, noises from the output system, and radiation noises. The conventional countermeasures against electromagnetic noises include covering the outside portions of resin package 5, through which the power supply terminal 6, the grounding terminal 7 and the output terminal 8 extend, with feed-through capacitors 10 or connecting the outside portions of the resin package 5 to chip capacitors. Recently, a semiconductor chip that includes a noise filter circuit therein has been disclosed.

FIG. 11 is a circuit diagram describing the structure of a pressure sensor incorporating therein a conventional noise filter circuit. The pressure sensor shown in FIG. 11 utilizes existing resistors 13 and 14 connected directly to a first power supply line V in a contact current circuit 11 and an existing resistor 15 connected directly to the first power supply line V in an amplifier current 12 and connects capacitors 16, 17, and 18 to the existing resistors 13, 14, and 15, respectively, to configure a first filter circuit. A second filter circuit is configured by disposing a second power supply line V′ different from the first power supply line V and by connecting a resistor 23 and a capacitor 24 to the second power supply line V′. Further, a third filter circuit is configured by connecting a resistor 25 and a capacitor 26 to the output of an operational amplifier 22, as disclosed in Japanese Patent Publication No. 3427594 (hereafter Reference 1).

A semiconductor apparatus including a noise filter circuit disposed between a power supply pad or an output pad and a circuit, in which the wiring length between the power supply pad or the output pad and the noise filter circuit is shorter than the wiring length between a grounding pad and the noise filter circuit, is disclosed in JP P Hei. 9 (1997)-45855 A (hereafter Reference 2). In the low-pass filter disclosed in Reference 2, a capacitor is inserted between the power supply pad or the output pad and the grounding pad. And, considering the inductance components of the wiring connected, the wiring length between the power supply pad or the output pad and the capacitor is set shorter than the wiring length between the grounding pad and the capacitor.

The filter circuit disclosed in Reference 1 that employs the structure thereof and the filter constants thereof for the design parameters, however, is not sufficient for countermeasuring against electromagnetic noises since the influences of the electromagnetic noises change greatly depending on the parasitic capacitance of the wiring. Therefore, it is very important to control the parasitic capacitance on the chip.

In the filter circuit disclosed in the Reference 2, the wiring connecting a power supply pad or an output pad and a capacitor and the wiring connecting a grounding pad and the capacitor are connected in series at the capacitor. Therefore, to flow noise signals to the ground, it is necessary to reduce the impedance parasitic on the wiring connecting the power supply pad or the output pad to the capacitor and the impedance parasitic on the wiring connecting the grounding pad and the capacitor so as not to adversely affect the capacitor impedance. In other words, it is necessary to clarify the resistance components and the inductance components parasitic on the wiring, and it is important to control the resistance components and the inductance components parasitic on the wiring.

In view of the foregoing, there remains a need to clarify the parasitic resistance components and the wiring inductance components, which concern the influences of electromagnetic noises, and to provide a semiconductor apparatus and a physical quantity sensing apparatus provided with sufficient countermeasures against electromagnetic noises. The present invention addresses this need.

### SUMMARY OF THE INVENTION

The present invention relates to a semiconductor apparatus and a physical quantity sensing apparatus that incorporate a filter circuit for countermeasuring against electromagnetic noises (hereinafter referred to sometimes as a “noise filter circuit” or simply as a “filter circuit”).

One aspect of the present invention is a semiconductor apparatus and a physical quantity sensing apparatus that include an internal circuit, a filter circuit for countermeasuring against electromagnetic noises, a power supply pad, a grounding pad, and a signal pad. The filter circuit can comprise resistance means and capacitance means. The power supply pad is for applying a power supply potential from the outside. The grounding pad is for applying a ground potential. The signal pad can be for inputting, outputting, or inputting and outputting signals. The length and the width of wiring between the signal or power supply pad and the internal circuit are set so that the resistance value Rf of the resistance means and the parasitic resistance component R1 of the wiring satisfy the following relational expression R1/Rf×100<25.

Another aspect of the present invention is a semiconductor apparatus and a physical quantity sensing apparatus that include the internal circuit, the power supply pad, the grounding pad, the signal pad, and a filter circuit comprising the capacitance means, which can be connected between the signal or power supply pad and the grounding pad. The length and the width of wiring between the signal or power supply pad and the capacitance means and the length and the width of wiring between the capacitance means and the grounding pad are set so that the impedance Za caused by the parasitic resistance component Ra and the inductance component La of the wiring between the signal or power supply pad and the capacitance means, the impedance Zk caused by the parasitic resistance component Rk and the inductance component Lk of the wiring between the capacitance means and the grounding pad, and the impedance Zc caused by the capacitance component of the capacitance means always satisfy the following relational expression Za+Zk<Zc in the frequency range of the electromagnetic noises to be cut.

The internal circuit, the filter circuit, the power supply pad, the grounding pad, and the signal pad can be formed in a single semiconductor chip. The capacitance means can be connected between the signal or power supply pad and the grounding pad by wiring. The signal pad can be an output pad for outputting signals to the outside. The internal circuit can comprise a physical quantity detecting element and an amplifier circuit for amplifying the signal output from the physical quantity detecting element. The capacitance means can be a capacitor.

### BRIEF DESCRIPTION OF THE DRAWINGS

FIG. 1 is a set of curves relating the inductance with the wiring length and the wiring width.

FIG. 2 is a block circuit diagram showing the configuration of a first embodiment of a pressure sensor according to the present invention.

FIG. 3 is a block circuit diagram showing the filter circuit of FIG. 1 for countermeasuring against electromagnetic noises.

FIG. 4 is a curve relating the ratio of the parasitic resistance component to the resistance component in the filter circuit for countermeasuring against electromagnetic noises with the noise withstanding capability.

FIG. 5 is a block circuit diagram showing part of the filter circuit for countermeasuring against electromagnetic noises in a second embodiment of a pressure sensor according to the present invention.

FIG. 6 is a set of curves describing the frequency characteristics of the impedance caused by the wiring inductance component and the capacitance component of the capacitor in the filter circuit for countermeasuring against electromagnetic noises.

FIG. 7 is a curve relating the wiring inductance component and the radiative electromagnetic noise withstanding capability.

FIG. 8 is a block circuit diagram showing the remaining portion of the noise filter circuit of the second embodiment.

FIG. 9 is a perspective view showing the external appearance of a conventional pressure sensor used in the intake manifold of an automobile engine.

FIG. 10 is a cross sectional view of the conventional pressure sensor of FIG. 9 taken along the extending direction of the power supply terminal thereof.

FIG. 11 is a circuit diagram describing the structure of a pressure sensor incorporating therein a conventional filter circuit for countermeasuring against electromagnetic noises.

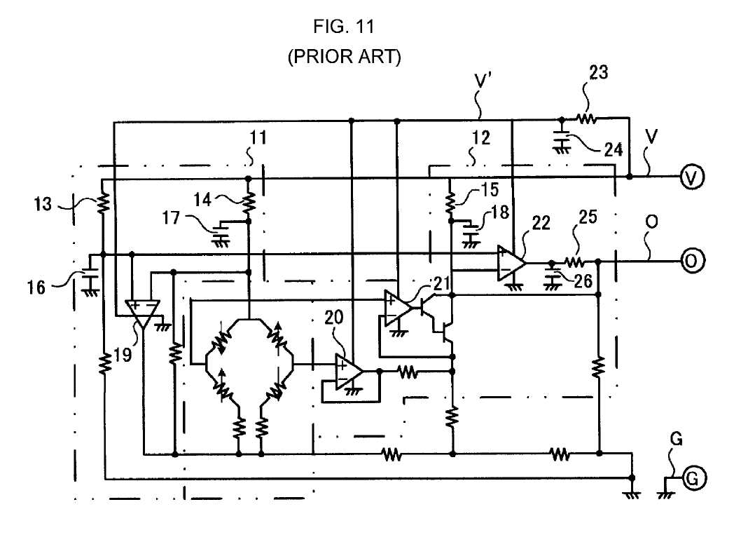

### DETAILED DESCRIPTION

The present invention is described in detail in reference with the accompanied drawing figures, which illustrate the preferred embodiments of the present invention. In the following, descriptions are made in connection with the embodiments of a semiconductor pressure sensor, to which the present invention is applied. Throughout the following descriptions and the accompanied drawing figures, the same reference numerals are used to designate the same or like constituent elements and their duplicated descriptions are omitted for the sake of simplicity.

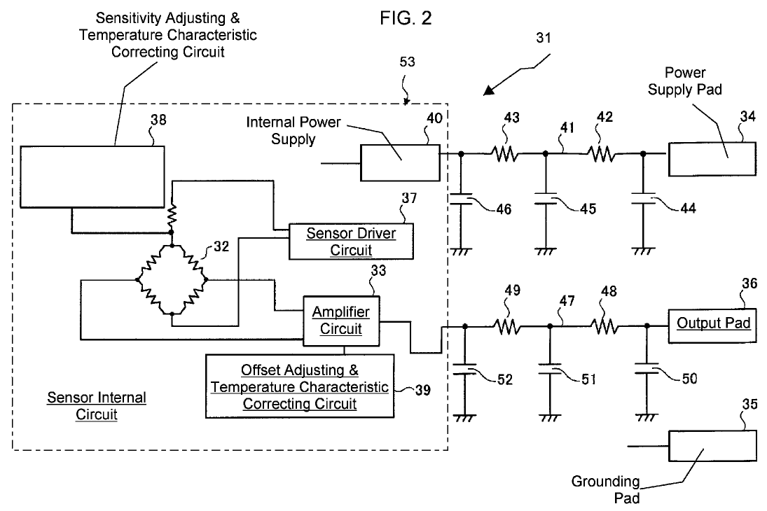

Referring to FIG. 2, a pressure sensor 31 includes a sensor internal circuit 53 comprising a Wheatstone bridge circuit 32 consisting of four piezoresistance elements that convert the pressure exerted thereto to a strain and an amplifier circuit 33 that amplifies the signal output from the Wheatstone bridge circuit 32. The Wheatstone bridge circuit 32 corresponds to a physical quantity detecting element. The internal circuit 53 can further include a sensor driver circuit 37 for driving the Wheatstone bridge circuit 32, a sensitivity adjusting and temperature characteristics correcting circuit 38 for adjusting the sensitivity of the Wheatstone bridge circuit 32 and correcting the temperature characteristics of the sensitivity of the Wheatstone bridge circuit 32, and an offset adjusting and temperature characteristics correcting circuit 39 for adjusting the offset of amplifier circuit 33 and correcting the temperature characteristics of the offset of amplifier circuit 33, and an internal power supply 40.

The pressure sensor 31 further includes a power supply pad 34 for applying a power supply potential from the outside, a grounding pad 35 for applying the ground potential from the outside, and an output or signal pad 36 for outputting signals to the outside. The signal pad 36 can also be an input pad for inputting signals or for inputting and outputting signals. A first resistor 42 and a second resistor 43 are connected in series to a wiring 41 connecting the power supply pad 34 to the internal power supply 40. A first capacitor 44 is connected between the grounding point and the connection node of the power supply pad 34 and the first resistor 42. A second capacitor 45 is connected between the grounding point and the connection node of the first resistor 42 and the second resistor 43. A third capacitor 46 is connected between the grounding point and the connection node of the second resistor 43 and the internal power supply 40. Two resistors 42 and 43 can constitute resistance means. Three capacitors 44, 45, and 46 can constitute capacitance means. The resistance means and the capacitance means can constitute a noise filter circuit. A similar noise filter circuit, comprising a third resistor 48, a fourth resistor 49, a fourth capacitor 50, a fifth capacitor 51, and a sixth capacitor 52, is connected to a wiring 47 connecting the output pad 36 and the amplifier circuit 33.

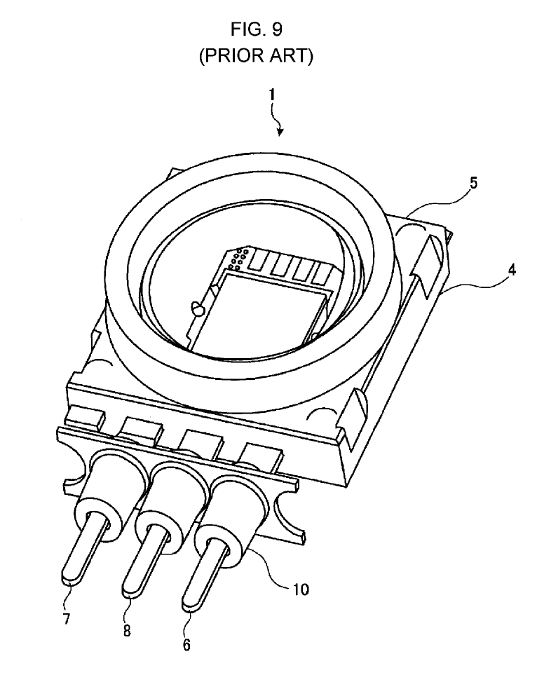

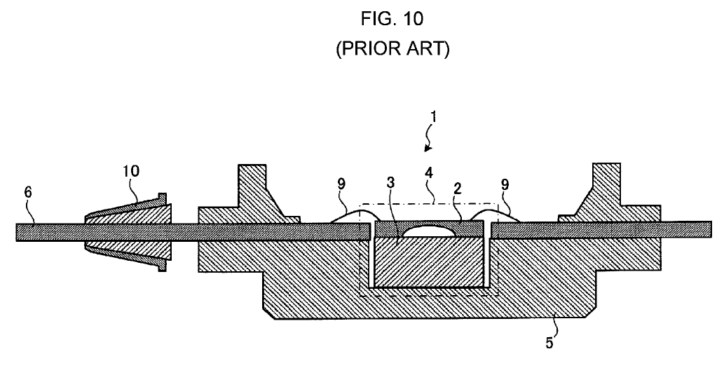

The configurations described above can be disposed in a semiconductor pressure sensor chip. The pressure sensor 31 includes a pressure detecting element including a glass pedestal and a semiconductor pressure sensor chip bonded to the glass pedestal, similarly as illustrated in FIGS. 9 and 10. The pressure detecting element is fixed to the window section of a resin package with an adhesive. The power supply pad 34, the grounding pad 35, and the output pad 36 of the pressure sensor 31 are electrically connected respectively to a power supply terminal, a grounding terminal, and an output terminal, extending through the resin package, via aluminum (Al) or gold (Au) wires. The window section of the resin package is filled with a gel. The external appearance and the structure in the cross section, along through which the power supply terminal extends, of the pressure sensor 31 are similar to that shown in FIGS. 9 and 10. The feed-through capacitors 10, however, are omitted in the embodiment of FIG. 2.

Typically, the frequencies of the electromagnetic noises applied to the automotive sensors fall within the range between several hundreds kHz and 1 GHz. Consequently, the parasitic resistance components and the inductance components of the wiring connecting the pads on a sensor chip and the filter circuits and the parasitic resistance component and the inductance component of the wiring connecting the filter circuit and the amplifier circuit cannot be ignored in determining the filter constants of the filter circuit formed in the sensor chip for cutting electromagnetic noises.

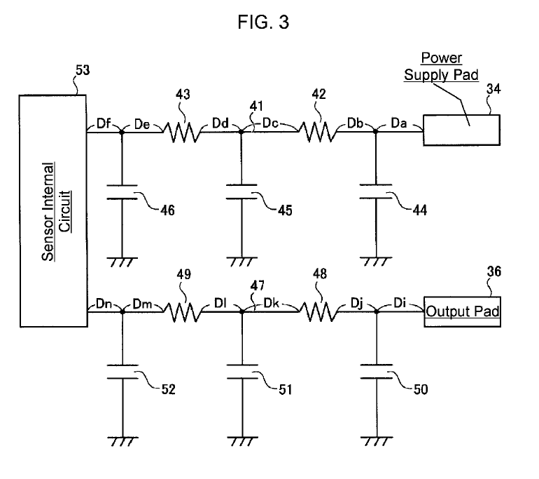

According to the first embodiment, attentions are paid, to the wiring 41 (FIG. 3) connecting the internal power supply 40 of the internal circuit 53 and the power supply pad 34, to the parasitic resistance component R1a of the wiring between the power supply pad 34 and the first resistor 42 of the noise filter circuit, the parasitic resistance component R1b of the wiring between the first resistor 42 and the second resistor 43, and the parasitic resistance component R1c of the wiring between the second resistor 43 and the internal power supply 40. The parasitic resistance values R1a, R1b, and R1c are adjusted or set so that the total parasitic resistance components R1=R1a+R1b+R1c and the sum Rf of the resistance values Rfa and Rfb of the first and second resistors 42 and 43, that is Rf=Rfa+Rfb, satisfy the following relational expression: R1/Rf×100<25.

For adjusting or setting the parasitic resistance component R1a of the wiring between the power supply pad 34 and the first resistor 42, it is effective to appropriately adjust the length Da and the width of the wiring section between the power supply pad 34 and the connection node of the first capacitor 44 and the length Db and the width of the wiring section between the connection node of the first capacitor 44 and the first resistor 42. For adjusting the parasitic resistance component R1b of the wiring between the first resistor 42 and the second resistor 43, it is effective to appropriately adjust the length Dc and the width of the wiring section between the first resistor 42 and the connection node of the second capacitor 45 and the length Dd and the width of the wiring section between the connection node of the second capacitor 45 and the second resistor 43. For adjusting the parasitic resistance component R1c on the side of the internal power supply 40, it is effective to appropriately adjust the length De and the width of the wiring section between the second resistor 43 and the connection node of the third capacitor 46 and the length Df and the width of the wiring section between the connection node of the third capacitor 46 and the internal power supply 40 of the internal circuit 53.

The parasitic resistance component R1 with respect to the output pad 36 is adjusted in the same manner as described above. For adjusting the parasitic resistance component R1a of the wiring between the output pad 36 and the third resistor 48, it is effective to appropriately adjust the length Di and the width of the wiring section between the output pad 36 and the connection node of the fourth capacitor 50 and the length Dj and the width of the wiring section between the connection node of the fourth capacitor 50 and the third resistor 48. For adjusting the parasitic resistance component R1b of the wiring between the third resistor 48 and the fourth resistor 49, it is effective to appropriately adjust the length Dk and the width of the wiring section between the third resistor 48 and the connection node of the fifth capacitor 51 and the length Dl and the width of the wiring section between the connection node of the fifth capacitor 51 and the fourth resistor 49. For adjusting the parasitic resistance component R1c on the side of the amplifier circuit 33, it is effective to appropriately adjust the length Dm and the width of the wiring section between the fourth resistor 49 and the connection node of the sixth capacitor 52 and the length Dn and the width of the wiring section between the connection node of the sixth capacitor 52 and the amplifier circuit 33 (internal circuit 53).

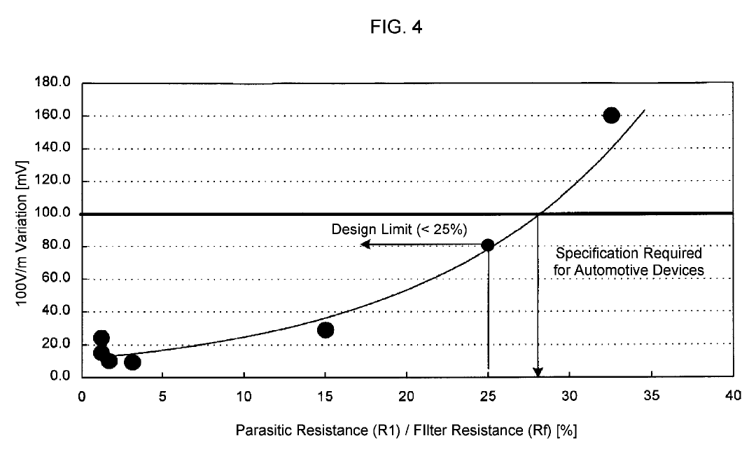

For example, when the resistance values of the first resistor 42 and the second resistor 43 are the same 60Ω, the resistance value Rf in the noise filter circuit on the power supply side is 120Ω(=60Ω+60Ω). Similarly for the output side, when the resistance values of the third resistor 48 and the fourth resistor are the same 60Ω, the resistance value Rf in the noise filter circuit on the output side is 120Ω(=60Ω+60Ω). As illustrated in FIG. 4, if the relation between the output variations caused by the radiative electromagnetic noise irradiation (vertical axis) and the ratio of the total parasitic resistance component R1=R1a+R1b+R1c and the resistance value Rf of the noise filter circuit (horizontal axis) satisfies the relational expression R1/Rf×100<25, a sensing apparatus meeting the required specifications for automotive sensors can be obtained.

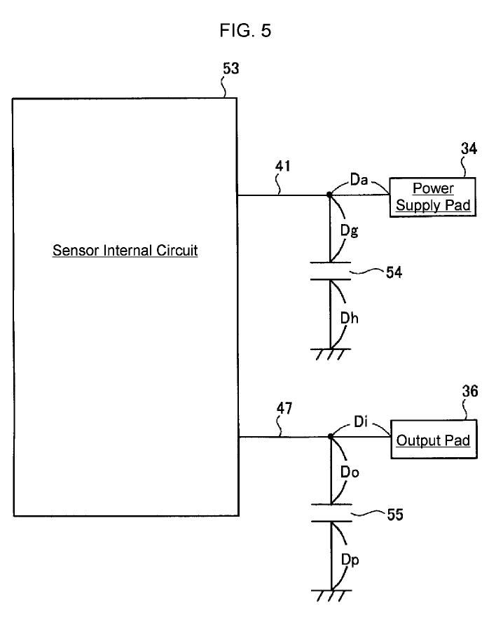

FIG. 5 is a block circuit diagram showing the noise filter circuit of a second embodiment of a pressure sensor. In the second embodiment, the noise filter circuit includes a first capacitor 54 and a second capacitor 55 for countermeasuring against electromagnetic noises. The first capacitor 54 (capacitor means) is connected between the power supply pad 34 and the grounding point. The lengths and the widths of the wiring sections are adjusted or set so that the impedance Za caused by the parasitic resistance component Ra and the inductance component La of the wiring connecting the power supply pad 34 and the first capacitor 54 (wiring sections Da and Dg in FIG. 5), the impedance Zk caused by the parasitic resistance component Rk and the inductance component Lk of the wiring connecting the first capacitor 54 and the grounding point (a wiring section Dh in FIG. 5), and the impedance Zc caused by the capacitance component of the first capacitor 54 satisfy the following relational expression Za+Zk<Zc in the frequency range of the electromagnetic noises to be cut.

The second capacitor 55 (capacitor means) is connected between the output pad 36 and the grounding point. In the same manner as in the noise filter circuit on the power supply side, the lengths and the widths of the wiring sections are adjusted or set so that the impedance Za caused by the parasitic resistance component Ra and the inductance component La of the wiring connecting the output pad 36 and the second capacitor 55 (wiring sections Di and Do in FIG. 5), the impedance Zk caused by the parasitic resistance component Rk and the inductance component Lk of the wiring connecting the second capacitor 55 and the grounding point (a wiring section Dp in FIG. 5), and the impedance Zc caused by the capacitance component of the second capacitor 55 satisfy the following relational expression Za+Zk<Zc in the frequency range of the electromagnetic noises to be cut.

The impedance Z of the wiring and the capacitance means to be considered is given by following Expression (1), where f, R, L and C stand for the electromagnetic noise frequency in Hz, the parasitic resistance in Ω, the inductance in H, and the capacitance, respectively, and where the induced reactor XL and the capacitive reactor XC of the wiring impedance are included:
Z=\sqrt{R²+(XL−XC)²} (1),
XL=2πfL (2),
XC=1/(2πfC) (3).

The wiring inductance L is given by the following Expression (4), where D, w, and t are the wiring length in m, the wiring width in m, and the wiring thickness in m, and where μ₀ is the magnetic permeability that is 4π×10⁻⁷:
L=(D×μ₀/2π)(In{2×D/(w+t)}+0.5+0.2235×(w+t)/D) (4).

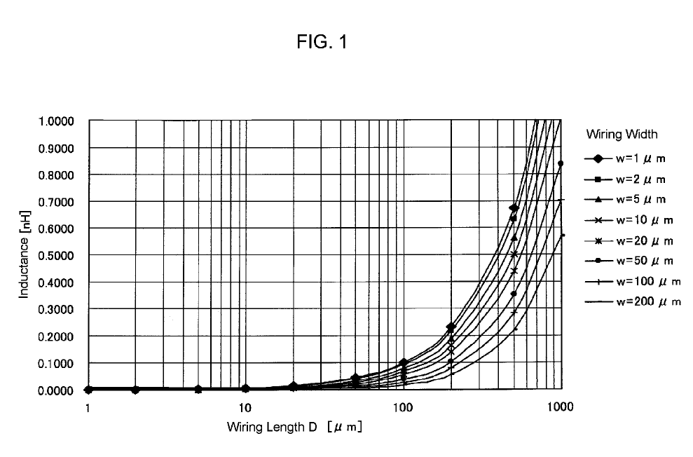

The dependence of the inductance on the wiring length and the wiring width obtained from Expression (4) is illustrated in FIG. 1, which illustrates a set of curves relating the inductance L with the wiring length D with the wiring width w a parameter at the wiring thickness of 1 μm. FIG. 1 indicates that the wiring impedance Za caused by the parasitic resistance component Ra and the inductance component La of the wiring connecting the power supply pad 34 or the output or signal pad 36 and the capacitance means and the wiring impedance Zk caused by the parasitic resistance component Rk and the inductance component Lk of the wiring connecting the capacitance means and the grounding pad 35 can be reduced by shortening the wiring length and by widening the wiring width. Therefore, it is possible to satisfy the relational expression Za+Zk<Zc always in the frequency range of the electromagnetic noises to be cut. Here, Zc is the impedance caused by the capacitance component of the capacitor means.

The induced reactor YL in the wiring impedance due to the inductance component is proportional to the electromagnetic noise frequency f as Expression (2) describes. The capacitance reactor XC is inversely proportional to the electromagnetic noise frequency f as Expression (3) describes. Therefore, as the electromagnetic noise frequency f becomes high, the induced reactor YL caused by the inductance component will not be ignorable and the impedance ZL caused by the inductance component parasitic on the wiring connecting the power supply pad 34 or the output pad 36 and the grounding point will be predominating over the impedance Zc caused by the capacitance component of the capacitor 54 or 55 in the noise filter circuit connecting the power supply pad 34 or the output pad 36 and the grounding point. Consequently, the filter effects will be impaired.

The impedance ZL caused by the inductance component is given by the sum Za+Zk of the impedance Za caused by the parasitic resistance component Ra and the inductance component La of the wiring connecting the power supply pad 34 or the output pad 36 and the capacitor 54 or 55 in the noise filter circuit (the wiring sections Da and Dg or the wiring sections Di and Do in FIG. 5) and the impedance Zk caused by the parasitic resistance component Rk and the inductance component Lk of the wiring connecting capacitor 54 or 55 and the grounding point (the wiring section Dh or Dp in FIG. 5).

The inductance component La is given by Expression (4) using the wiring length Da+Dg or Di+Do between the power supply pad 34 or the output pad 36 and the capacitor 54 or 55 and the wiring width w thereof. In the same manner, the inductance component Lk is given by Expression (4) using the wiring length Dh or Dp between the capacitor 54 or 55 and the grounding point and the wiring width w thereof. In Expression (4), D stands for Da+Dg, Dh, Di+Do, or Dp. The wiring thickness is 1.0 μm. The inductance of the path between the power supply pad 34 or the output pad 36 and the capacitor 54 or 55 is given by La+Lk. The impedance Za+Zk is derived from the inductance component La+Lk.

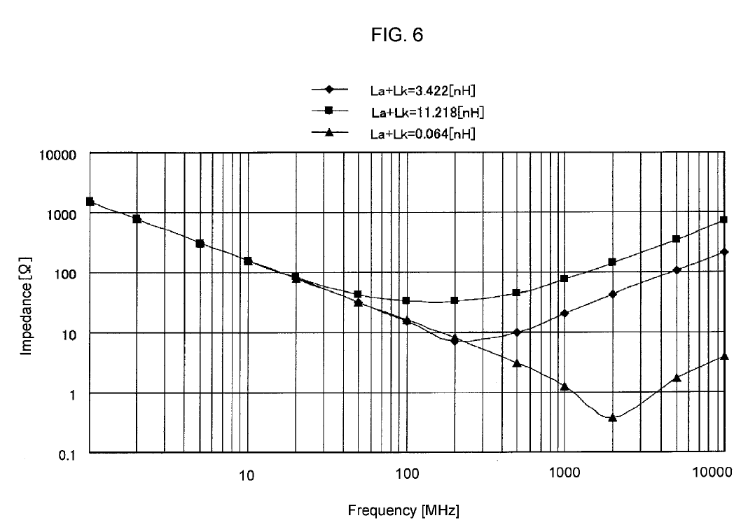

FIG. 6 shows characteristics curves describing the frequency characteristics of the impedance Za+Zk caused by the wiring inductance component La+Lk and the capacitance component (set at 100 pF) of the capacitor 54 or 55 in the noise filter circuit. FIG. 6 indicates that as the inductance component La+Lk becomes so large as not to be ignored with reference to the capacitance component of the capacitor 54 or 55, the impedance becomes too large to make noise signals flow to the ground potential in the frequency range higher than from 100 to 200 MHz. Therefore, the effects of the filter are impaired. The electromagnetic noises applied to the automotive sensors are in the frequency range between several hundreds kHz and 1 GHz. Therefore, when the impedance becomes large in the frequency range higher than from 100 to 200 MHz as shown in FIG. 6, the noise removal capability around several hundreds kHz is impaired and variations are caused in the sensor output.

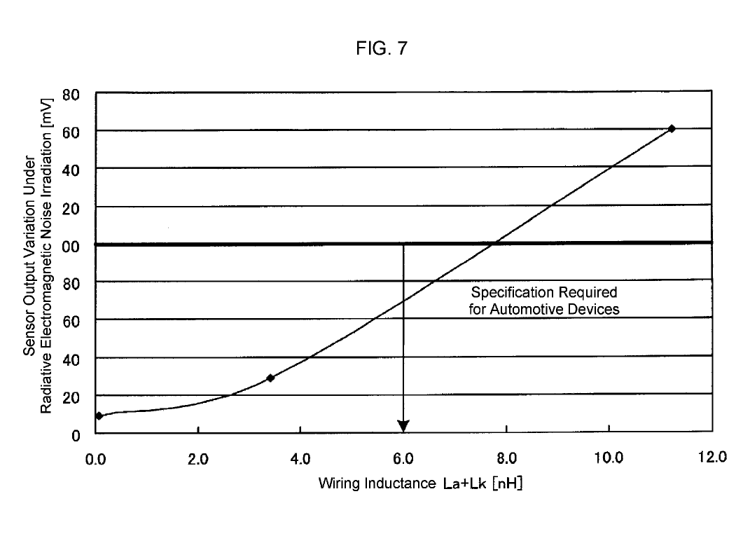

FIG. 7 is a curve relating the wiring inductance component La+Lk and the radiative electromagnetic noise withstanding capability. The capacitance of the capacitor 54 or 55 in the noise filter circuit is 100 pF. As illustrated in FIG. 7, the electromagnetic noise withstanding capability can be improved, if the inductance component La+Lk is reduced by adjusting the wiring length and the wiring width so that the induced reactor XL can be ignored with respect to the capacitive reactor XC of the capacitor 54 or 55.

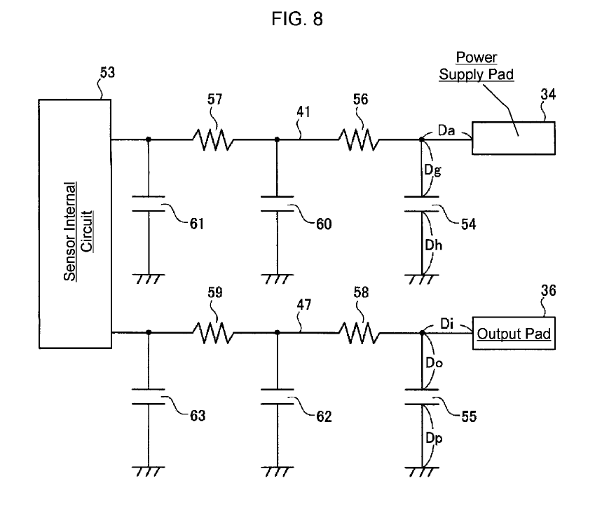

FIG. 8 is a block circuit diagram showing the remaining portion of the noise filter circuit of the second embodiment. Here, a CR filter circuit including resistors 56 and 57 or 58 and 59 and capacitors 60 and 61 or 62 and 63 can be connected, with no problem, between the power supply pad 34 or the output pad 36 and the sensor internal circuit 53, in addition to the capacitor 54 or 55 connected between the power supply pad 34 or the output pad 36 and the grounding point. In the circuit shown in FIG. 8, two resistors 56 and 57 are connected in series with the wiring 41 connecting the sensor internal circuit 53 and the power supply pad 34, between the connection node of the first capacitor 54 and the sensor internal circuit 53.

The capacitor 60 is connected between the connection node of the two resistors 56, 57 and the grounding point. The capacitor 61 is connected between the connection node of the sensor internal circuit 53 and the resistor 57 and the grounding point. The two resistors 58 and 59 are connected in series with the wiring 47 connecting the sensor internal circuit 53 and the output pad 36, between the connection node of the second capacitor 55 and the sensor internal circuit 53. The capacitor 62 is connected between the connection node of the two resistors 58, 59 and the grounding point. The capacitor 63 is connected between the connection node of the sensor internal circuit 53 and the resistor 59 and the grounding point.

Countermeasures against electromagnetic noises required for the automotive sensors can be obtained by adjusting the length and the width of the wiring between the power supply pad or the output pad and the internal circuit so that the parasitic resistance component R1 of the wiring between the power supply pad or the output pad and the internal circuit and the resistance value Rf of the resistance means in the filter circuit can satisfy the relational expression R1/Rf×100<25, as disclosed in the first embodiment. Similarly, countermeasures against electromagnetic noises required for the automotive sensors also can be obtained by adjusting the length and the width of the wiring between the power supply pad or the output pad and the internal circuit so that the impedance Za of the wiring between the power supply pad or the output pad and the capacitance means in the filter circuit, the impedance Zk of the wiring between the capacitance means and the grounding pad, and the impedance Zc of the capacitance means always satisfy the relational expression Za+Zk<Zc in the frequency range of the electromagnetic noises to be cut.

A semiconductor apparatus and a physical quantity sensing apparatus that can withstand electromagnetic noise required for automotive devices are obtained. Since the chip that incorporates a noise filter circuit therein makes it unnecessary to connect a discrete filter device thereto, the manufacturing costs can be reduced and any fault due to the connection of the discrete filter device can be prevented. Thus, inexpensive and very reliable semiconductor apparatuses and various sensing apparatuses can be realized.

Although the invention has been described in connection with the illustrated embodiments, changes and modifications are obvious to those skilled in the art without departing from the true spirits of the invention. Therefore, the invention should be understood not by the specific descriptions made in connection with the embodiments thereof. For example, the dimensions and the electrical characteristics values described in connection with the embodiments are exemplary. The invention is applicable not only to pressure sensors but also to various kinds of sensors and semiconductor apparatuses other than sensors. Although the pressure sensor according to the invention have been described in connection with the output pad for outputting signals, the pressure sensor according to the invention can include an input pad for inputting signals or a signal pad for inputting signals and for outputting signals.

As described above, the semiconductor apparatus and the physical quantity sensing apparatus according to the invention are advantageous for the environments prone to electromagnetic noises. The semiconductor apparatus and the physical quantity sensing apparatus according to the invention are suited especially for automotive use, for measurement and for correction.

While the present invention has been particularly shown and described with reference to particular embodiments, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on, and claims priority to, JP PA 2005-133557, filed on 28 Apr. 2005. The disclosure of the priority application, in its entirety, including the drawings, claims, and the specification thereof, is incorporated herein by reference.

What is claimed is:

1. A semiconductor apparatus comprising:
an internal circuit;
a filter circuit for countermeasuring against electromagnetic noises, the filter circuit comprising resistance means and capacitance means;
a power supply pad for applying a power supply potential from the outside;
a grounding pad for applying a ground potential; and
a signal pad for inputting signals, outputting signals, or inputting and outputting signals,
wherein the length and the width of wiring between the signal or power supply pad and the internal circuit are set so that the resistance value Rf of the resistance means and the parasitic resistance component R1 of the wiring satisfy the relational expression R1/Rf×100<25.

2. The semiconductor apparatus according to claim 1, wherein the internal circuit, the filter circuit, the power supply pad, the grounding pad, and the signal pad are formed in a single semiconductor chip.

3. The semiconductor apparatus according to claim 2, wherein the capacitance means is connected between the power supply pad and the grounding pad by wiring.

4. The semiconductor apparatus according to claim 2, wherein the capacitance means is connected between the signal pad and the grounding pad by wiring.

5. A semiconductor apparatus comprising:
an internal circuit;
a power supply pad for applying a power supply potential from the outside;
a grounding pad for applying a ground potential;
a signal pad for inputting signals, outputting signals, or inputting and outputting signals; and
a filter circuit for countermeasuring against electromagnetic noises, the filter circuit comprising capacitance means connected between the signal or power supply pad and the grounding pad,
wherein the length and the width of wiring between the signal or power supply pad and the capacitance means and the length and the width of wiring between the capacitance means and the grounding pad are set so that the impedance Za caused by the parasitic resistance component Ra and the inductance component La of the wiring between the signal or power supply pad and the capacitance means, the impedance Zk caused by the parasitic resistance component Rk and the inductance component Lk of the wiring between the capacitance means and the grounding pad, and the impedance Zc caused by the capacitance component of the capacitance means always satisfy the relational expression Za+Zk<Zc in the frequency range of the electromagnetic noises to be cut.

6. The semiconductor apparatus according to claim 5, wherein the internal circuit, the filter circuit, the power supply pad, the grounding pad, and the signal pad are formed in a single semiconductor chip.

7. The semiconductor apparatus according to claim 5, wherein the capacitance means comprises a capacitor connected between the signal or power supply pad and the ground pad.

8. A physical quantity sensing apparatus comprising:
an internal circuit comprising a physical quantity detecting element and an amplifier circuit for amplifying the signal output from the physical quantity detecting element;
a filter circuit for countermeasuring against electromagnetic noises, the filter circuit comprising resistance means and capacitance means;
a power supply pad for applying a power supply potential from the outside;
a grounding pad for applying a ground potential; and
an output pad for outputting signals to the outside,
wherein the length and the width of wiring between the output or power supply pad and the internal circuit are set so that the resistance value Rf of the resistance means and the parasitic resistance component R1 of the wiring satisfy the relational expression R1/Rf×100<25.

9. The physical quantity sensing apparatus according to claim 8, wherein the internal circuit, the filter circuit, the power supply pad, the grounding pad, and the output pad are formed in a single semiconductor chip.

10. The physical quantity sensing apparatus according to claim 9, wherein the capacitance means is connected between the power supply pad and the grounding pad by wiring.

11. The physical quantity sensing apparatus according to claim 9, wherein the capacitance means is connected between the output pad and the grounding pad by wiring.

12. A physical quantity sensing apparatus comprising:
an internal circuit comprising a physical quantity detecting element and an amplifier circuit for amplifying the signal output from the physical quantity detecting element;
a power supply pad for applying a power supply potential from the outside;
a grounding pad for applying a ground potential;
an output pad for outputting signals to the outside; and
a filter circuit for countermeasuring against electromagnetic noises, the filter circuit comprising capacitance means connected between the output or power supply pad and the grounding pad,
wherein the length and the width of wiring between the output or power supply pad and the capacitance means and the length and the width of wiring between the capacitance means and the grounding pad are set so that the impedance Za caused by the parasitic resistance component Ra and the inductance component La of the wiring between the output or power supply pad and the capacitance means, the impedance Zk caused by the parasitic resistance component Rk and the inductance component Lk of the wiring between the capacitance means and the grounding pad, and the impedance Zc caused by the capacitance component of the capacitance means always satisfy the relational expression Za+Zk<Zc in the frequency range of the electromagnetic noises to be cut.

13. The physical quantity sensing apparatus according to claim 12, wherein the internal circuit, the filter circuit, the power supply pad, the grounding pad, and the output pad are formed in a single semiconductor chip.

14. The physical quantity sensing apparatus according to claim 12, wherein the capacitance means comprises a capacitor connected between the signal pad and the ground pad.

15. The physical quantity sensing apparatus according to claim 12, wherein the capacitance means comprises a capacitor connected between the power supply pad and the ground pad.
